(19) United States
(12) Patent Application Publication
(10) Pub. No.: US 2026/0020406 A1
(43) Pub. Date: Jan. 15, 2026

(54) DISPLAY DEVICE

(71) Applicant: Samsung Display Co., Ltd., Yongin-Si (KR)

(72) Inventors: Joon Yong PARK, Yongin-si (KR); Ju Hyun LEE, Yongin-si (KR); SAMTAE JEONG, Yongin-si (KR)

(21) Appl. No.: 19/185,248

(22) Filed: Apr. 22, 2025

(30) Foreign Application Priority Data
Jul. 15, 2024 (KR) 10-2024-0093187

(51) Int. Cl. H10H 29/41; H01L 25/16; H10D 86/60; H10H 29/39; H10H 29/80

(52) U.S. Cl. CPC H10H 29/41; H01L 25/167; H10D 86/60; H10H 29/39; H10H 29/8323

(57) ABSTRACT

The present disclosure provides a display device including: a substrate; a plurality of transistors positioned on the substrate; an insulating layer positioned on the transistors; a light emitting device positioned on the insulating layer and electrically connected to the transistors; a partition wall and a spacer positioned on the insulating layer, and a protective layer on the spacer, the protective layer including an IZO doped with 5 at % to 10 at % of tin. The protective layer reduces pressure on the spacer and minimizes etching of an electrode during formation of the spacer.

### CROSS-REFERENCE TO RELATED APPLICATION

This application claims priority to and the benefit of Korean Patent Application No. 10-2024-0093187 filed at the Korean Intellectual Property Office on Jul. 15, 2024, the entire contents of which are incorporated herein by reference.

### BACKGROUND

### (a) Field of the Invention

The present disclosure relates to a display device.

### (b) Description of the Related Art

The display device is a device that visually displays data. Today, such display devices have various applications. Furthermore, as display devices become thinner and lighter, their range of applications is expanding.

A mask is used during the manufacturing process of a display device. A light emitting layer, etc. of a display device may be formed by this mask. The mask may be made of a metal, and during a manufacturing process using the mask, a spacer that supports the mask may be stamped or pressed.

### SUMMARY

Embodiments attempt to provide a display device capable of reducing or preventing any undesirable result caused by stamping and pressing on a spacer and minimizing the etching of an electrode during formation of the spacer.

An embodiment of the present disclosure provides a display device including: a substrate; a plurality of transistors positioned on the substrate; an insulating layer positioned on the transistors; a light emitting device positioned on the insulating layer and electrically connected to the transistors; a partition wall and a spacer positioned on the insulating layer; and a protective layer on the spacer, wherein the protective layer includes an IZO doped with 5 at % to 10 at % of tin.

The partition wall and the spacer may be connected, and an uppermost portion of the spacer may be positioned further from the substrate than an upper surface of the partition wall.

A step portion having a thickness that is smaller than that of the partition wall and the spacer may be positioned between the partition and the spacer.

The light emitting device may include: a first electrode electrically connected to the transistor; a light emitting layer on the first electrode in an opening of the partition wall; and a second electrode positioned on the light emitting layer, wherein the first electrode may have a multi-layer structure of ITO/Ag/ITO.

The second electrode may be on the partition wall and the spacer.

The second electrode may be on the protective layer.

The protective layer may include an IZO doped with 6 at % to 9 at % of tin.

A first part of the second electrode positioned on the partition wall and a second part of the second electrode positioned on the spacer may be separated from each other.

The second electrode may be on the step portion.

The filling layer may include an organic material.

Another embodiment of the present disclosure provides an electronic device including: a substrate with a plurality of light emitting devices thereon; a spacer positioned on the substrate; and a protective layer on the spacer, wherein the protective layer includes an IZO doped with 5 at % to 10 at % of tin.

It may further include a partition wall connected to the spacer, and the uppermost portion of the spacer may be farther from the substrate than the upper surface of the partition wall.

The protective layer may not be positioned on the partition wall.

The step portion having a smaller thickness than that of the partition wall and the spacer may be positioned between the partition and the spacer.

The protective layer may not be positioned on the step portion.

An upper surface of the spacer may have a curved shape.

The protective layer may include an IZO doped with 6 at % to 9 at % of tin.

The light emitting device may include a first electrode, a light emitting layer and a second electrode, the second electrode positioned on the partition wall and the second electrode positioned on the spacer may include portions separated from each other, and the first electrode may have a structure of ITO/Ag/ITO.

It may further include a cover glass positioned on the spacer.

A filling layer may be positioned between the spacer and the cover glass.

According to the embodiments, it may be possible to provide a display device capable of preventing stamping and pressing of a spacer and minimizing etching of an electrode when forming a spacer.

According to embodiments, an electronic device includes the display device as described herein.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

FIG. 1 schematically illustrates a cross-section of a display device according to another embodiment.

FIG. 2 illustrates an enlarged view of a portion indicated by “A” in FIG. 1.

FIG. 3 to FIG. 5 illustrate a process of forming a protective layer.

FIG. 6 illustrates an XRD spectrum of an IZO doped with 6 at % tin.

FIG. 7 illustrates an XRD spectrum of an IZO doped with 9 at % tin.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts of the description that are not essential for understanding the disclosure are omitted. Like numerals refer to like or similar components throughout the specification.

Further, since sizes and thicknesses of constituent members shown in the accompanying drawings are arbitrarily chosen for better understanding and ease of description, the present disclosure is not limited to the illustrated sizes, scale, and thicknesses. In the drawings, the thicknesses of layers, films, panels, regions, etc., are exaggerated for clarity. In the drawings, for better understanding and ease of description, the thicknesses of some layers and areas are exaggerated.

It should be understood that when an element such as a layer, film, region, or substrate is referred to as being “on” another element, it can be directly on the other element or intervening elements may be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly stated to the contrary, the word “comprise” and variations such as “comprises” and “comprising” should be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

A display device according to an embodiment can be applied to various electronic devices. The electronic device according to one embodiment includes the display device described below, and may further include a module or device having additional functions in addition to the display device.

Hereinafter, a display device according to an embodiment will be described with reference to the drawings.

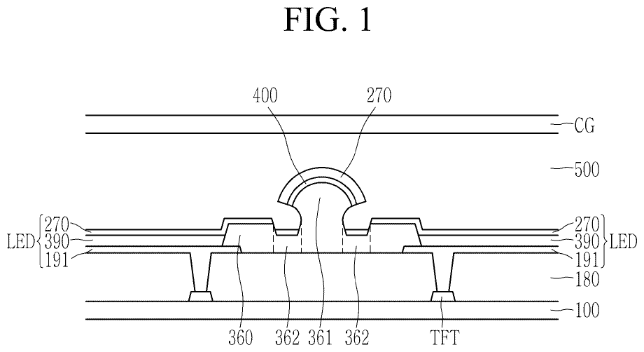

FIG. 1 schematically illustrates a cross-section of a display device according to another embodiment. Referring to FIG. 1, a display device according to the present embodiment may include a first substrate 100, a plurality of transistors TFT positioned on the first substrate 100, and an insulating layer 180. A first electrode 191 and a partition wall 360 are positioned on the insulating layer 180, and the first electrode 191 may be positioned in an opening of the partition wall 360 and may be connected to the transistor TFT. As will be described separately later, a portion of the partition wall 360 may form a spacer 361. The partition wall 360 and the spacer 361 are continuously formed.

Although not specifically illustrated, the transistor TFT may include a semiconductor layer, source and drain electrodes connected to the semiconductor layer, and a gate electrode insulated from the semiconductor layer. A second electrode 270 may be positioned on the partition wall 360, and a light emitting device layer 390 may be positioned between the first electrode 191 and the second electrode 270. The first electrode 191, the second electrode 270, and the light emitting device layer 390 are collectively referred to as a light emitting device LED.

The first electrode 191 and the second electrode 270 may each include a conductive oxide such as an indium tin oxide (ITO), an indium zinc oxide (IZO), a zinc tin oxide (ZTO), a copper indium oxide (CIO), a copper zinc oxide (CZO), a gallium zinc oxide (GZO), an aluminum zinc oxide (AZO), a tin oxide (SnO₂), a zinc oxide (ZnO), or a combination thereof, or a conductive polymer such as calcium (Ca), ytterbium (Yb), aluminum (Al), silver (Ag), magnesium (Mg), samarium (Sm), titanium (Ti), gold (Au) or an alloy thereof, graphene, a carbon nanotube, or PEDOT:PSS. However, the first electrode 191 and the second electrode 270 are not limited thereto, and may be formed in a stacked structure of two or more layers.

In an embodiment, the first electrode 191 may be a reflective electrode having a structure of ITO/Ag/ITO, and the second electrode 270 may be a transflective electrode including AgMg. Light generated from the light emitting device layer 390 may be reflected by the first electrode 191, which is a reflective electrode, and may resonate between the second electrode 270, which is a transflective electrode, and the first electrode 191 to be amplified. The resonated light may be reflected from the first electrode 191 to be emitted through an upper surface of the second electrode 270.

Alternatively, the second electrode 270 may be a reflective electrode having a structure of ITO/Ag/ITO, and the first electrode 191 may be a transflective electrode including AgMg. Light generated from the light emitting device layer 390 may be reflected by the second electrode 270, which is a reflecting electrode, and may resonate between the first electrode 191, which is a transflective electrode, and the second electrode 270 to be amplified. The resonated light may be reflected from the second electrode 270 to be emitted to an upper surface of the first electrode 191.

The second electrode 270 may be positioned on the partition wall 360 and the spacer 361. As illustrated in FIG. 1, the second electrode 270 may have a first part that is positioned on the partition wall 360 and a second part that is positioned on the spacer 361, and the two parts may be separated from each other. A step portion 362 positioned between the partition wall 360 and the spacer 361 may also have the second electrode 270 thereon (the third part of the second electrode 270). The third part of the second electrode 270 is not continuously connected with either the first part or the second part. In the embodiment of FIG. 1, the step portion 362 has a smaller thickness than the partition wall 360, and may therefore be depicted as a lower step relative to the upper surface of the partition wall 360. A protective layer 400 may be positioned between the spacer 361 and the second electrode 270. Configurations of the spacer 361 and the protective layer 400 will be described in detail below.

Referring to FIG. 1, a cover glass CG may be positioned. A filling layer 500 may be positioned in a space between the cover glass CG and the partition wall 360 and the spacer 361. The filling layer 500 may include an organic material. Although not shown, a sealing layer, a touch sensing layer, and a polarization layer may be positioned between the charge layer 500 and the cover glass CG.

In the present embodiment, the filling layer 500 may be positioned in a space above the spacer 361 and the partition wall 360. If the filling layer 500 is not positioned above the spacer 361 and the partition wall 360 and an air gap is positioned, there may be a problem of increased reflectivity at an interface or occurrence of spots on a panel. However, in the case of the present embodiment, interference by internal light may be minimized and the problem of spots occurring in the panel may be resolved by filling the space above the spacer 361 and the partition wall 360 with an organic material.

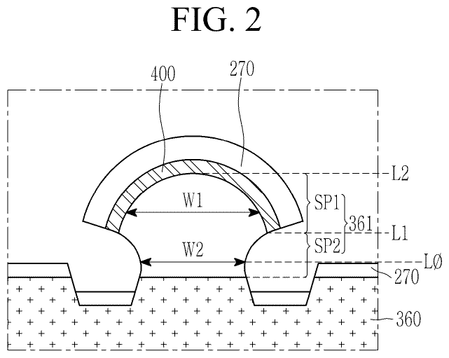

FIG. 2 illustrates an enlarged view of a portion indicated by “A” in FIG. 1. Referring to FIG. 2, a portion of the partition wall 360 may protrude to constitute the spacer 361. The spacer 361 may maintain a gap between the mask and the substrate 100 during a process of depositing a light emitting layer, etc. using a mask during a manufacturing process of the display device, thereby preventing the display device from being stamped or torn by the mask during the deposition process.

The spacer 361 may include the same material as the partition wall 360, and may be formed with the same material as that of the partition wall 360 at different heights using a half-tone mask when forming the partition wall 360.

The spacer 361 may be formed of an organic material such as polyimide or hexamethyldisiloxane (HMDSO).

Three imaginary lines, line L0, line L1, and line L2 are shown in FIG. 2, extending parallel to an upper surface of the substrate 100. The spacer 361 may include a first portion SP1 that increases in width as it gets closer to the substrate 100, and a second portion SP2 positioned between the first portion SPI and the substrate 100 and having a width that decreases in a direction toward the substrate 100. For example, in the first portion SP1, a first width W1 of the spacer 361 in a direction parallel to the upper surface of the substrate 100 may increase in going from line L2, which is farthest from the substrate 100, to line L1, which is closer to the substrate than line L2. In contrast, in the second portion SP2, a second width W2 of a first spacer in a direction parallel to the upper surface of the substrate 100 may decrease as it approaches the substrate, going from line L1 to a line L0. That is, the first portion SP1, which is an upper region of the spacer 361, may have a reverse taper, and the second portion SP2, which is a lower region of the spacer 361, may have a regular tapered shape.

If the upper region of the spacer 361 is formed to have a regular tapered shape, a contact area between the mask and the spacer 361 may increase in a deposition process using the mask, which may in turn increase particles generated by the mask. However, in the present embodiment, the particles generated by the mask may be reduced because the mask contact area is made small by forming the upper region of the spacer 361 to have a reverse taper.

As shown in FIG. 2, the protective layer 400 and the second electrode 270 may be positioned on the spacer 361. As described above, the spacer 361 may be an area where a mask is to be positioned in a process for forming a light emitting layer, etc., and an upper portion of the spacer 361 may be pressed by the mask. In this case, outgas, etc.

may be released from the upper portion of the spacer 361. In particular, in the present embodiment, the filling layer 500 may be positioned above the partition wall 360 and the spacer 361, so the outgas from the partition wall 360 and the spacer 361 may be discharged. Furthermore, if the spacer 361 is pressed against the mask, it may be visible to a user as a stain or a dark spot.

However, in the display device according to the present embodiment, the protective layer 400 may be positioned above the spacer 361. The protective layer 400 may include a metal, and may be positioned above the spacer 361 to protect the spacer 361 and prevent the spacer 361 from being pressed or stamped.

The protective layer 400 according to the present embodiment may include an

IZO doped with a low concentration of tin. Specifically, the protective layer 400 according to the present embodiment may include an IZO doped with tin in an amount of 5 at % (atomic percent) to 10 at % (atomic percent), more specifically 6 at % (atomic percent) to 9 at % (atomic percent). In this case, the doping concentration may be a concentration measured excluding oxygen content in the IZO, and the content of indium and zinc in the IZO of the present embodiment may be 1:1. However, this is an example, and the present disclosure is not limited thereto.

As will be described in detail separately later, the protective layer 400 having the above composition may protect the spacer 361, and reduce or prevent damage to the first electrode 191 during a formation process by the action of rapid etching when forming the protective layer 400.

In order to form the protective layer 400 above the spacer 361, a process of forming a corresponding material on an entire surface of the panel and then etching it may be required.

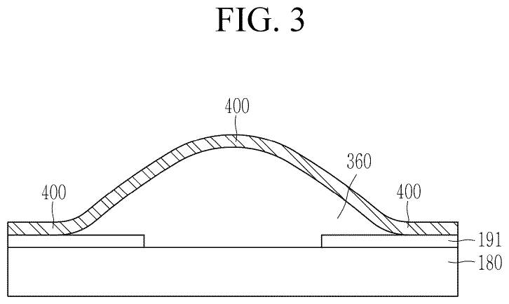

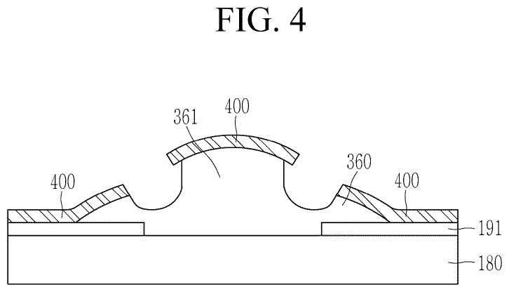

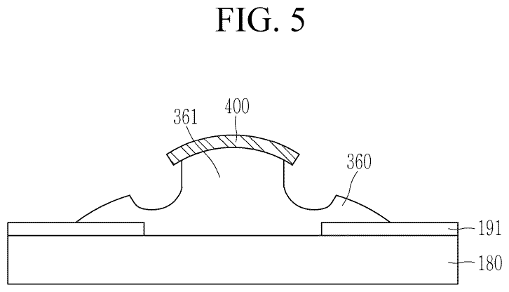

FIG. 3, FIG. 4, and FIG. 5 illustrate a process of forming the protective layer 400. As illustrated in FIG. 3, the protective layer 400 may be formed above the first electrode 191 and the entire partition wall 360. Next, as shown in FIG. 4, a portion of the protective layer 400 may be etched, and the partition wall 360 may be additionally etched through a portion where the protective layer 400 is removed to form a step portion and the spacer 361 having the shape depicted in FIG. 2. Next, as shown in FIG. 5, the protective layer 400 may be formed above the spacer 361 by etching the protective layer 400.

Damage to the first electrode 191 may occur during the etching process of the protective layer 400. An etchant for etching the protective layer 400 may etch an ITO positioned above the first electrode 191. In this way, when a portion of the first electrode 191 is etched during the process of forming the protective layer 400, Ag may be eluted from the first electrode made of ITO/Ag/ITO (multi-layer structure). To prevent this problem, etching of the protective layer 400 has to happen fast.

Table 1 below measures and illustrates a degree of Ag elution according to an etching time and an etching rate (%). As shown in Table 1 below, when the etching time decreases, the etching rate (%) may also decrease, and the Ag elution amount may also decrease as confirmed by an Ag elution test result.

TABLE 1

| Etching time | Etch rate | |
|---|---|---|
| (E/T, second) | (O/E, %) | Ag elution assay |
| 94″ | 270 | 15 pt. |
| 76″ 18″↓ | 200 | 4 pt. (defect reduction) |

Accordingly, the display device according to the present embodiment used an IZO doped with low concentration of tin as the protective layer 400. For example, a display device according to an embodiment may include the IZO doped with 6 at % to 9 at % tin. The IZO containing such a low concentration of tin may be etched quickly, thereby increasing etching speed, and thus reducing the amount of time that the first electrode 191 is exposed to the etchant during formation of the protective layer 400. This way, damage to the first electrode 191 is reduced.

Table 2 below shows etching speeds measured for various materials of the protective layer 400.

TABLE 2

| | Materials of protective layer | Wet etch | |
|---|---|---|---|
| Comparative | IGZO (ref.) | 33.3 | (Å/sec) |
| Example 1 | | | |
| Example 1 | Low Sn IZO (Sn 6 at %) | 103.6 | (Å/sec, 310%↑) |
| Example 2 | Low Sn IZO (Sn 9 at %) | 63.7 | (Å/sec, 191%↑) |

Referring to Table 2 above, it was confirmed that Examples 1 and 2, which were doped with low concentrations of tin, had significantly faster etching speeds than Comparative Example 1. As shown in Table 2 above, it was confirmed that when the etching rate of Comparative Example 1 was set to 100%, the etching rate of Example 1 doped with 6 at % tin increased by 310%, and the etching rate of Example 2 doped with 9 at % tin increased by 191%. Hence, according to the present embodiment, the IZO doped with a low concentration of tin had a faster etching speed than the conventional IGZO. Accordingly, the time required for the etching process may be minimized, and damage to the first electrode 191 may be minimized during the etching process for forming the protective layer 400.

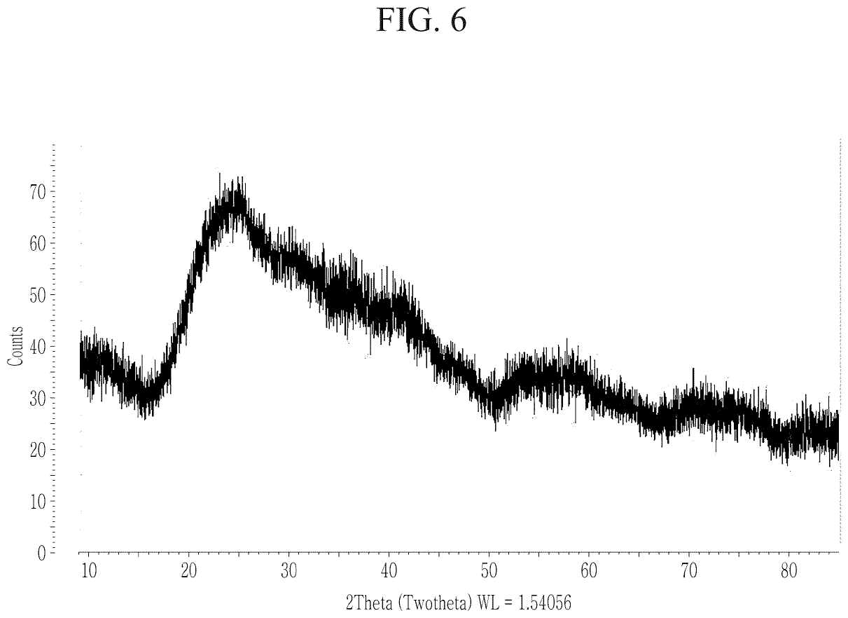

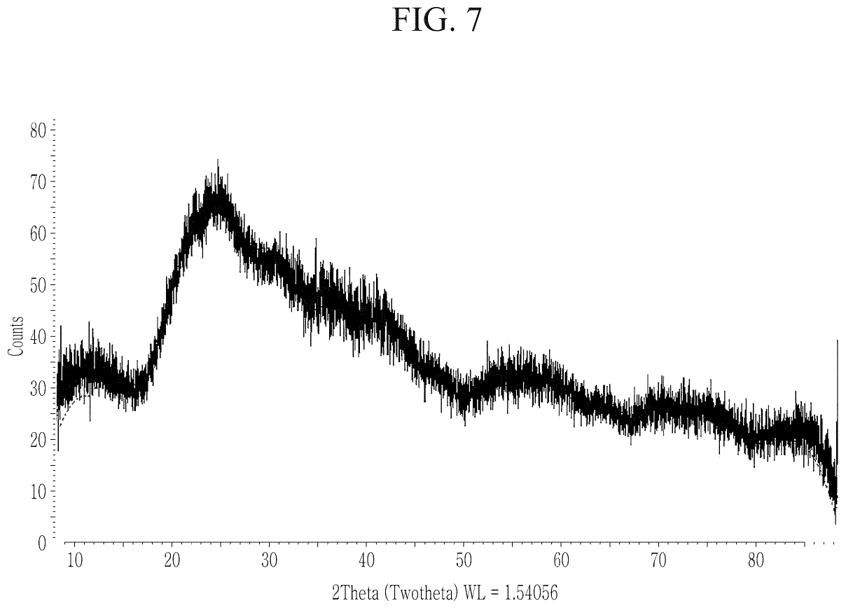

A suitable material for the protective layer 400 maintains an amorphous state even after a heat treatment process. For the IZO having compositions of Examples 1 and 2 above, an XRD spectrum was measured to confirm crystallinity after heat treatment at 260° C., and the results are shown in FIGS. 6 and 7, respectively.

FIG. 6 illustrates an XRD spectrum of an IZO doped with 6 at % tin. FIG. 7 illustrates an XRD spectrum of an IZO doped with 9 at % tin. Referring to FIG. 6 and FIG. 7, no crystalline peak was observed in each spectrum, and it was confirmed that the low-concentration doped IZO maintained an amorphous state even after the heat treatment process.

Furthermore, it may be desirable that the material of the protective layer 400 have an etching selectivity in an etching process of an inorganic layer (e.g., SiNx). Table 3 shows a degree to which the protective layer 400 is etched when etching an inorganic layer (SiNx) for various materials.

TABLE 3

| Material | Etching amount |
|---|---|
| Sn-doped IZO | 17.2 nm |
| IZO | 17.1 nm |
| IGZO | 17.2 nm |

Referring to Table 3 above, it was confirmed that the low-concentration tin-doped IZO according to the present embodiment exhibited an etching degree similar to that of the IZO or IGZO. That is, according to the present embodiment, it was confirmed that the IZO doped with low-concentration tin has an etching selectivity in the SiNx etching process, which is preferable during the process.

As described above, the display device according to the present embodiment may include a protective layer positioned on a spacer, and the protective layer may include a low-concentration Sn-doped IZO. This protective layer may prevent the spacer from being stamped or pressed, and may prevent outgas from being released from the spacer.

Furthermore, the protective layer may include a low-concentration tin-doped IZO with a fast etching rate, so the etching process for forming the protective layer may be performed without causing any notable damage to the first electrode during the protective layer formation process.

The display device disclosed herein may be incorporated into various electronic devices, such portable electronic devices including mobile phones, smartphones, tablet personal computers (PCs), mobile communication terminals, electronic notebooks, e-books, portable multimedia players (PMPs), navigations, and ultra mobile PCs (UMPCs), but also televisions (TVs), laptops, monitors, billboards, Internet of Things (IoT), or the like. According to an embodiment, the display device of this disclosure may also be used in wearable electronic devices such as smart watches, watch phones, glasses-type displays, or head mounted displays (HMDs). According to an embodiment, the display device of the disclosure may also be used in electronic devices in vehicles, such as vehicle dashboards, center information displays (CIDs) of the center fascia or dashboards of vehicles, mirror displays that replace the side view mirrors of vehicles, and display screens arranged on the rear sides of front seats to serve as entertainment devices for back seat passengers of vehicles.

According to embodiments, an electronic device includes the display device as described herein.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

What is claimed is:

1. A display device comprising:
a substrate; and
a plurality of transistors positioned on the substrate;
an insulating layer positioned on the transistors;
a light emitting device positioned on the insulating layer and electrically connected to the transistors;
a partition wall and a spacer positioned on the insulating layer; and
a protective layer on the spacer,
wherein the protective layer includes an IZO doped with 5 at % to 10 at % of tin.

2. The display device of claim 1, wherein
the partition wall and the spacer are connected, and
an uppermost portion of the spacer is positioned further from the substrate than an upper surface of the partition wall.

3. The display device of claim 2, further comprising:
a step portion having a smaller thickness than that of the partition wall and the spacer, is the step portion being positioned between the partition and the spacer.

4. The display device of claim 2, wherein
the light emitting device includes: a first electrode electrically connected to the transistor;
a light emitting layer on the first electrode in an opening of the partition wall; and
a second electrode positioned on the light emitting layer,
wherein the first electrode has a multi-layer structure of ITO/Ag/ITO.

5. The display device of claim 4, wherein
the second electrode is on the partition wall and the spacer.

6. The display device of claim 4, wherein
the second electrode is on the protective layer.

7. The display device of claim 1, wherein
the protective layer includes an IZO doped with 6 at % to 9 at % of tin.

8. The display device of claim 5, wherein
a first part of the second electrode positioned on the partition wall and a second part of the second electrode positioned on the spacer are separated from each other.

9. The display device of claim 4, wherein
the second electrode is on the step portion.

10. The display device of claim 9, wherein
the filling layer comprises an organic material.

11. An electronic device comprising:
a substrate with a plurality of light emitting devices thereon;
a spacer positioned on the substrate; and
a protective layer on the spacer, wherein the protective layer includes an IZO doped with 5 at % to 10 at % of tin.

12. The electronic device of claim 11, further comprising
a partition wall connected to the spacer,
wherein an uppermost portion of the spacer is farther from the substrate than an upper surface of the partition wall.

13. The electronic device of claim 12, wherein
the protective layer is not positioned on the partition wall.

14. The electronic device of claim 12, further comprising:
a step portion having a thickness less than that of the partition wall, wherein the spacer is positioned between the partition and the spacer.

15. The electronic device of claim 14, wherein
the protective layer is not positioned on the step portion.

16. The electronic device of claim 11, wherein
an upper surface of the spacer has a curved shape.

17. The electronic device of claim 11, wherein
the protective layer includes an IZO doped with 6 at % to 9 at % of tin.

18. The electronic device of claim 11, wherein
the light emitting device includes a first electrode, a light emitting layer and a second electrode,
a first part of the second electrode positioned on the partition wall and a second part of the second electrode positioned on the spacer are separated from each other, and
the first electrode has a structure of ITO/Ag/ITO.

19. An electronic device comprising:
a display device, wherein the display device includes,
a substrate; and
a plurality of transistors positioned on the substrate;
an insulating layer positioned on the transistors;
a light emitting device positioned on the insulating layer and electrically connected to the transistors;
a partition wall and a spacer positioned on the insulating layer; and
a protective layer on the spacer,
wherein the protective layer includes an IZO doped with 5 at % to 10 at % of tin.

20. The electronic device of claim 19,
wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
